(19) United States
(12) Patent Application Publication
(10) Pub. No.: US 2011/0039039 A1
(43) Pub. Date: Feb. 17, 2011

(54) WETTING A SURFACE OF A SOLID SUBSTRATE WITH A LIQUID METAL

(75) Inventors: Fergal O'reilly, Dublin (IE); Kenneth Fahy, Dublin (IE)

Correspondence Address: THE NATH LAW GROUP, 112 South West Street, Alexandria, VA, 22314, US

(73) Assignee: UNIVERSITY COLLEGE DUBLIN, NATIONAL UNIVERSITY OF IRELAND, DUBLIN, Dublin (IE)

(21) Appl. No.: 12/988,443

(22) PCT Filed: Apr. 21, 2009
(86) PCT No.: PCT/EP09/02891

§ 371 Date: Oct. 18, 2010

(30) Foreign Application Priority Data
Apr. 30, 2008 (IE) S2008/0336

(51) Int. Cl. C23C 14/14; B05C 9/10

(52) U.S. Cl. 427/597; 118/620

(57) ABSTRACT

A method of wetting a surface of a solid substrate with a liquid metal, comprises activating said surface with a high energy beam; and introducing the liquid metal to the surface while in the active state, the temperature of the surface being above the melting point of the liquid metal.

### FIELD OF THE INVENTION

This invention relates to a method of wetting a surface of a solid substrate with a liquid metal.

### BACKGROUND

WO2007/051537 discloses system for providing extreme ultraviolet (EUV) radiation comprising a laser source arranged to produce a focussed laser beam and a carrier movable relative to the laser source for carrying a surface material, the surface material when carried by the carrier providing a renewable target edge. The focussed beam is arranged to impinge on the target edge to produce an EUV radiation emitting plasma. The system is cooperable with a mirror for harnessing the EUV radiation by reflecting EUV radiation impinging thereon. The mirror comprises a substantially aspheric surface and means for supplying a reflecting liquid to at least partially coat the aspheric surface, the mirror being rotatable to uniformly distribute and/or centrifugally confine the liquid on the aspheric surface. A particular material which it is desirable to use as a target edge and a liquid coating for the mirror is Galinstan, an alloy of Gallium having a composition of 68.5% Ga, 21.5% In and 10% Sn, and which is liquid at room temperature.

A problem arising is to prepare a substrate surface to make it suitably wettable for such alloys.

“Wetting of metal surfaces with a liquid metal using a plasma interaction technique”, T. S Sudarshan, M. H. Lim, L. Park, and S. H. Chang, J. Vac. Sci. Technol. A 2 1503 1984, describes a method for wetting mercury onto various metal substrates. It relies on plasma activation of the metal substrate. “Wetting in the Au—Sn System”, Liang Yin, Stephen J. Meschter, Timothy J. Singler, Acta Materialia 52 (2004) 2873-2888 describes the wetting of gold substrates with liquid tin using the sessile drop technique. The experiments were performed in a gaseous reducing atmosphere over a range of substrate temperatures (250-430° C.) and concentrations with the optimum substrate temperature/concentration yielding a liquid tin film of thickness approximately 20 μm. However, this film is produced on a substrate which is at least partially soluble in the liquid metal.

“Pulsed laser deposition from solid and molten metals”, Tárnas Szörényi, Zoltán Kántor, Zsolt Tóth, Péter Heszler, Applied Surface Science 138-139 (1999) 275-279, describes pulsed laser deposition of molten metal onto a solid substrate held at a temperature far below the melting point of the metal. The liquid metal therefore solidifies immediately upon contact with the much cooler solid substrate.

WO2008029327 relates to a plasma discharge lamp for generating EUV radiation and/or soft X-rays by means of an electrically operated discharge. The lamp consists of at least two liquid metal coated electrodes. The plasma is ignited by a high power laser impinging on the liquid metal. The liquid metal coating is applied by chemically treating a porous substrate material.

US2001011545 discloses a laser cleaning process for removing contaminant particles from the surface of materials, such as semiconductor wafers. This is purely a cleaning method and does not form part of a liquid metal coating process.

U.S. Pat. No. 4,357,555 describes a rotary anode with liquid metal coated bearings. The wetting process consists of heating the bearing shaft and liquid metal in a reducing atmosphere of hydrogen gas.

U.S. Pat. No. 5,871,848 describes a method for wetting a graphite substrate with a boron alloy for use in generating an ion beam containing boron. At the wetting temperature, the boron reacts with the graphite which is then readily wet by the alloy.

### SUMMARY OF THE INVENTION

The invention provides a method of wetting a surface of a solid substrate with a liquid metal, comprising activating said surface with a high energy beam and introducing the liquid metal to the surface while in the active state, the temperature of the surface being above the melting point of the liquid metal.

The high energy beam may comprise a beam of photons, electrons, ions, molecules or atoms, or a combination of any number of these, with sufficient energy to ablate material from the surface of the solid substrate to be wetted, leaving pure bulk material behind. The ablation process leaves the surface of the substrate in a high surface energy, or active, state, and ready to bond with materials which will reduce the overall energy of the system. If the liquid metal is introduced to this active surface sufficiently quickly then the liquid metal can cover this active region. If there is a delay between the activation and the liquid metal deposition then the surface can become deactivated or passivated by oxidation or by other contaminants in the system.

In the case of a metal substrate, the surface energy of the cleaned bulk material (typically 300 mN/m to 1000 mN/m) is much higher than that of the oxide or other passivating layer normally found on metal surfaces. The cleaned high surface energy substrate is necessary as the surface tension (liquid surface energy) of the liquid metal is also very high (typically 300 mN/m to 1000 mN/m). This means that the liquid metal has a very high affinity for itself, and will form beads of liquid on any surface which has a much lower surface energy than it. If the liquid metal is deposited on a surface with a very high surface energy (such as an unpassivated clean metal) it will wet this surface, as the high energy surface will have a strong affinity for the liquid and vice versa.

From the chemical point of view, pure liquid metal can form metallic bonds with an underlying metallic substrate only if the underlying metallic surface is exposed. If an oxide layer (or a nitride layer or an organic contaminant layer, etc.) exists on the surface, then the liquid metal will not be able to form direct metallic bonds with the surface, and will preferentially form these bonds with itself, leaving the minimum possible surface area exposed, and thus beading up.

The embodiments of the invention use a high energy beam which progressively activates the substrate surface immediately in front of an advancing edge of the liquid metal. This may cause some of the liquid metal to be alloyed with the surface of the substrate, and this alloying may also assist in the liquid metal wetting the surface. We believe, however, that the wetting is primarily the result of the immediate covering of active, high energy, surface areas with liquid metal.

The high energy beam is preferably a laser beam, most preferably a pulsed laser beam, but an alternative high energy beam such as an ion beam, an atom beam, a molecular beam or an electron beam may be used in suitable circumstances.

In certain embodiments the surface is circularly symmetrical and is rotated about its axis during laser activation, the laser beam being deflected to successive radial positions during such rotation so that successive annular regions of the surface are activated by rotation of the surface.

In one embodiment the surface to be wetted comprises a substantially conical interior surface of the solid substrate. In that case the liquid metal may be introduced to the internal apex of the conical surface and distributed onto the active annular regions by at least one of centrifugal force and gravity.

In another embodiment the surface to be wetted comprises one side of a disk. In that case the liquid metal may be introduced to the active annular regions by rotation of the edge of the disk in a bath of liquid metal.

In a still further embodiment the surface to be wetted comprises the external surface of a cylinder. In that case the liquid metal may be introduced to the active annular regions by rotation of the lower part of the cylinder in a bath of liquid metal.

Still further, the surface to be wetted may comprise the inside surface of a hollow cylinder. In that case the liquid metal may be introduced to the inside of the cylinder and distributed onto the active annular regions by rotation of the cylinder.

The substrate surface may be rotated at different rates during activation and introduction of liquid metal.

Preferably the surface to be wetted is maintained in a vacuum or an inert atmosphere during laser activation and introduction of liquid metal.

The liquid metal may be liquid at room temperature, in which case the substrate need not be heated during the wetting process.

The substrate may be molybdenum, and the liquid metal may be Galinstan.

None of the prior documents consider high energy beam activation of a substrate to improve the wettability of a substrate surface to Gallium alloys or other liquid metals.

One application for the invention is in the EUV system referred to above (WO2007/051537), but a liquid metal coating could be used for applications at other wavelengths and for other purposes, such as plasma shielding.

### BRIEF DESCRIPTION OF THE DRAWINGS

Embodiments of the invention will now be described, by way of example, with reference to the accompanying drawings, in which:

FIG. 1 illustrates a method according to the preferred embodiment of the present invention.

FIG. 2 illustrates a method according to a second embodiment of the present invention.

### DESCRIPTION OF THE EMBODIMENTS

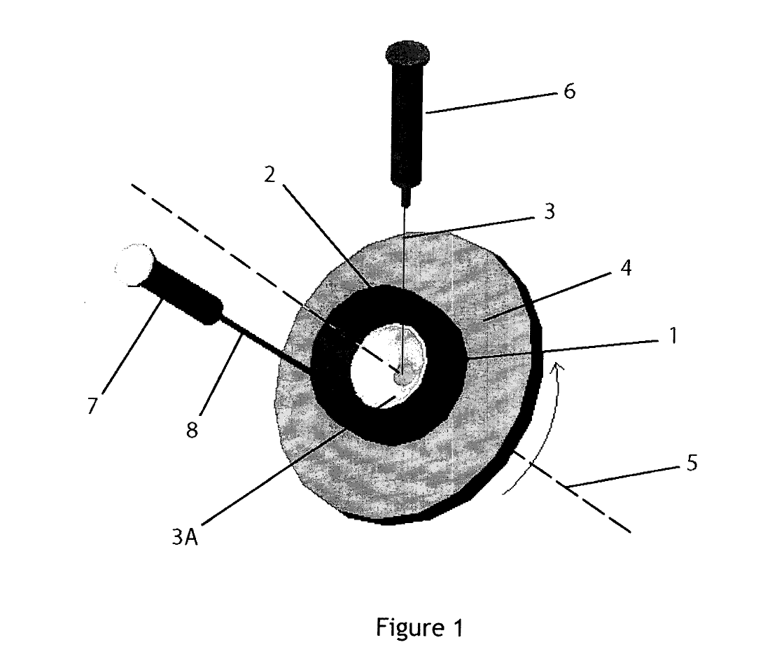

In FIG. 1, a solid substrate 1 has an approximately conical interior surface or depression 2, which is the surface to be wetted with liquid metal 3. The substrate 1 is mounted on a rotatable platform (turntable) 4 which can be driven at variable speeds by an electric motor, not shown, the conical surface 2 being substantially coaxial with the axis of rotation 5 of the turntable. The turntable axis 5 is tilted at an angle to the vertical. An actuator-controlled syringe 6 is mounted above the turntable in a position to drop liquid metal 3 onto the centre (apex) of the conical surface 2. A high power pulsed laser 7 produces an unfocussed beam 8 which can be deflected onto the conical surface 2 at any selected radial distance from the rotational axis 5. The direction of the beam 8 is controlled by an electronically-controlled prism, not shown.

In performing the method, the turntable 4 is set into rotation and the laser beam 8 is initially directed at the centre of the conical surface 2 and maintained there for sufficient time to clean and activate the region of the surface irradiated by the beam. Immediately thereafter, i.e. before the cleaned and activated region of the surface 2 has time to revert to its normal inactivate state, a small quantity of liquid metal 3 is dropped from the syringe 6 onto the laser activated region of the surface 2. The tilt of the turntable 4 and the rotation of the substrate 1 spreads the liquid metal 3 out by gravity and centrifugal force to wet the laser activated region of the surface 2. Alternatively, the activated region is rotated through a pool of the liquid metal which is formed at the lower part of the conical surface, the substrate 1 being maintained at such an angle that the liquid does not spill out.

After the first, central, region of the surface 2 has been wetted, the laser beam 8 is moved radially outwardly to impinge on a dry region of the surface 2 at a position just beyond the periphery of the previously activated and wetted region, and maintained there for sufficient time to clean and activate an annular region of the surface 2 contiguously surrounding the previously activated and wetted region. Then, while the newly activated annular region remains active, a further quantity of liquid metal is dropped onto the central portion of the surface 2 and the liquid metal spread out by gravity and centrifugal force to wet the newly active annular surface region.

This process, i.e. activation and wetting of an annular region surrounding the previously activated and wetted region, is repeated until the entire conical surface 2 has been progressively wetted with liquid metal. Since each successive annular laser-activated region has a greater area than the preceding region, due its greater radius, at each step of the process a progressively larger quantity of liquid metal is dispensed by the syringe 6. The pool of liquid which forms in the tower part of the rotating cone interacts continuously with the rotating active surface, and best results are achieved by having the activation process occur closest to the liquid pool, as even at a vacuum of below 10⁻⁴ millibar the surface deactivates rapidly, typically within seconds. The wetted region of the surface 2 at an intermediate stage of the process is indicated at 3A.

The laser 7 preferably has a wavelength of less than or equal to 1064 nm and is pulsed at a frequency of greater than 10 Hz, preferably 50 Hz, preferably with a pulse length of approximately 5 ns to 50 ns and preferably with a pulse energy of approximately 50 mJ to 500 mJ. The laser beam 8 is unfocused and preferably has a diameter of approximately 1 mm to 10 mm. In the preferred embodiment the solid substrate 1 is continuously rotated throughout the entire wetting process. For a fixed laser repetition rate of 50 Hz, the initial rate of rotation of the substrate may be approximately 100 rpm, and this may be decreased in one or several steps to approximately 10 rpm. The higher rates of rotation are used for regions closer to the centre of the substrate where the annular area of the treatment region is small, and the lower rotation rates are applied as regions further from the centre are treated, to take account of the larger areas to be treated. The lower limit on the rotation is set by the requirement to interact the active area with the liquid pool before the activity of the area diminishes, and this depends on how closely the region being activated is to the liquid pool. Using these decreasing rotation rates, at a fixed laser repetition rate of 50 Hz, with a laser pulse energy of approximately 500 mJ, and a laser pulse length of approximately 9 ns, an unfocused 1 cm diameter beam impinges at a rate of approximately 5 shots per centimetre of the length of annular area being treated.

The liquid metal 3 may be a gallium alloy, preferably Galinstan. Galinstan is an alloy of gallium, indium and tin that is liquid at room temperature, therefore allowing the method to be carried out at room temperature. Galinstan is corrosive and readily attacks certain metals such as aluminium. Galinstan readily reacts with oxygen and so forms a dull grey oxide layer when exposed to air.

The solid substrate 1 to be wetted is preferably formed of molybdenum or other corrosion resistant metal such as tungsten, tantalum or stainless steel. The molybdenum is corrosion resistant and will therefore resist attack from Galinstan and other corrosive liquid metals.

Prior to activation and wetting, the conical surface 2 of the substrate 1 is preferably mechanically polished with abrasive paper in air before the wetting process begins. Abrasive paper preferably of 18 μm grit size is used to provide the final polished surface. After mechanical polishing, the substrate is washed with water and allowed to dry in air.

The substrate angle of tilt, i.e. the angle of tilt of the axis 5, is preferably adjustable to allow the liquid metal to flow along the substrate towards the laser activated regions. By increasing the angle of tilt the excess liquid metal that may have accumulated on the substrate surface 2 will flow off the substrate leaving behind a thin clean liquid metal film.

The liquid metal film preferably has a thickness of approximately 1 μm-200 μm and preferably 100 μm.

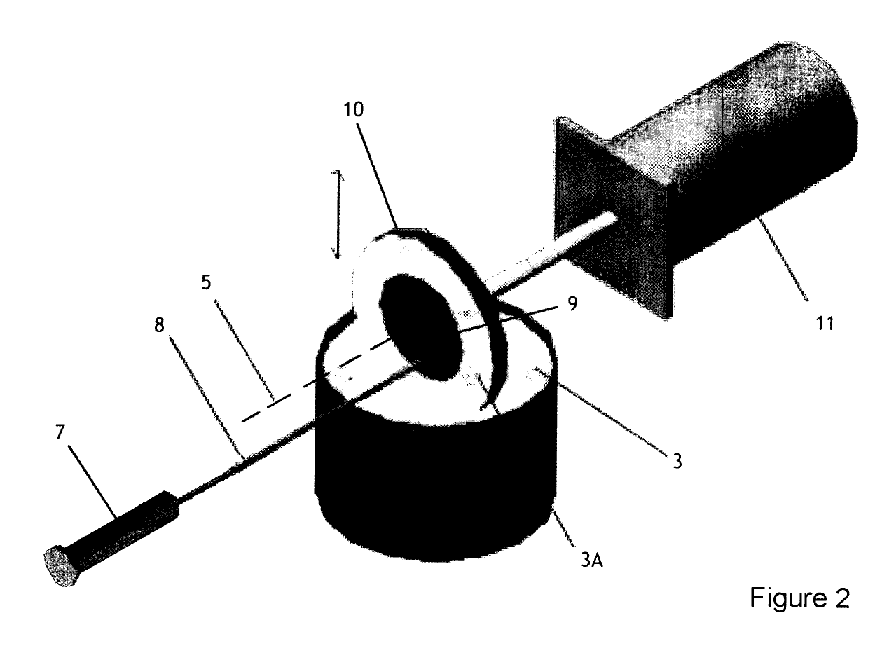

FIG. 2 shows a second embodiment of the invention. In FIG. 2 the same reference numerals have been used as in FIG. 1 for the same or equivalent components.

In this embodiment the surface to be wetted with liquid metal is the flat circular surface 9 on one side of a disk-like substrate 10. The substrate 10 is rotatable about its own centre axis 5 by an electric motor 11. The axis 5 is shown substantially horizontal but it could be at an acute angle to the horizontal. The vertical position of the entire motor and disk assembly is adjustable so that the disk 10 can be positioned above, or dipped to a varying degree into, a bath of liquid metal 3 below the disk.

In performing the method of the second embodiment, the disk 10, initially lifted clear of the bath of liquid metal 3, is set into rotation and the laser beam 8 is directed at the outer peripheral edge of the surface 9 so as to clean and activate an annular region of the surface 9 at that edge. Before the cleaned and activated annular region of the surface 9 has time to revert to its normal inactivate state, and while the disk is still rotating, the edge of the disk 10 is lowered into the bath so that a thin film of liquid metal 3 is formed over the activated region as the disk rotates through the bath. At the same time, due to the downward movement of the disk 10 relative to the laser beam, the laser beam 8 is now cleaning and activating a dry annular region of the surface 9 at a position just inside and contiguous with inside periphery of the previously activated and wetted region.

Then, while the newly activated dry annular region remains active, the disk 10 is further lowered into the bath of liquid metal 3, so that the newly activated region is wetted too. This process, i.e. activation and wetting of an annular region within and contiguous with the previously activated and wetted region, is repeated until the entire surface 9 has been progressively wetted with liquid metal. The substrate 10 can then be removed from the liquid metal bath and wetting is maintained, with a 1 μm to 200 μm film remaining on the surface. The uniformity of this film depends on rotation speed and excess liquid levels on the rotating substrate. The wetted region of the surface 9 at an intermediate stage of the process is indicated at 3A.

In a third embodiment, not shown, the substrate surface to be wetted is the internal surface of a hollow cylinder which is orientated on its side, i.e. with its axis of symmetry substantially horizontal. The surface is cleaned and activated using a high power pulsed laser beam as the cylinder is rotated around its axis, the beam being intermittently deflected to activate successive contiguous annular bands of the internal surface. The liquid metal is introduced inside the cylinder using an injection system such as a syringe or other such pump. As the cylinder is rotated part of the excess liquid which is collected in the bottom of the cylinder is distributed as a uniform film around the activated region of the inner surface of the cylinder.

In a fourth embodiment, also not shown, the substrate surface to be wetted is the external surface of a cylinder which is orientated on its side and rotated about its own axis with the lower part of the cylinder dipping in a liquid metal bath. The surface is cleaned and activated using a high power pulsed laser beam as the cylinder is rotated, the beam being intermittently deflected to activate successive contiguous annular bands of the external surface. As the activated region of the surface passes through the metal bath it becomes coated in liquid metal, forming a thin film.

In the second to fourth embodiments the characteristics of the laser 7 are preferably the same as for the first embodiment and, as before, the substrate (disk or cylinder) is preferably continuously rotated throughout the entire wetting process. The speed of rotation of the substrate may be variable between approximately 10 rpm to 300 rpm at various times during the wetting process.

The liquid metal may be a gallium alloy, such as Galinstan, and the solid substrate disk or cylinder to be wetted may be molybdenum or other corrosion resistant metal previously mentioned. Prior to activation and wetting, the surface of the substrate to be wetted is preferably mechanically polished with abrasive paper, washed and dried, as previously described.

In all embodiments the thickness of the liquid metal film can be adjusted by rotating the substrate at different rates, or by changing the temperature of the liquid metal to alter its viscosity.

Although not shown, in all embodiments surface activation and wetting is preferably carried out in a vacuum below 10⁻⁴ millibar or in an inert atmosphere to prevent oxidation and/or contamination of the active surface.

The invention is not limited to the embodiments described herein which may be modified or varied without departing from the scope of the invention.

1. A method of wetting a surface of a solid substrate with a liquid metal, comprising:
activating said surface with a high energy beam; and
introducing the liquid metal to the surface while in the active state, the temperature of the surface being above the melting point of the liquid metal
wherein said activating comprises progressively activating the substrate surface using said high energy beam immediately in front of an advancing edge of the liquid metal.

2. A method according to claim 1 wherein the high energy beam comprises any combination of a beam of: photons, electrons, ions, molecules or atoms, with sufficient energy to ablate material from the surface of the solid substrate to be wetted, leaving pure bulk material behind.

3. (canceled)

4. A method according to claim 1 wherein said high energy beam comprises: a laser beam, a pulsed laser beam, an ion beam, an atom beam, a molecular beam or an electron beam.

5. A method according to claim 1 wherein the surface is circularly symmetrical and comprising the step of rotating the surface about its axis during said activating

6. A method according to claim 5 comprising deflecting the laser beam to successive radial positions during said rotating so that successive annular regions of the surface are activated by rotation of the surface.

7. A method according to claim 6 wherein the surface to be wetted comprises a substantially conical interior surface of a solid substrate and comprising introducing the liquid metal to an internal apex of the conical surface and distributing the liquid metal onto the activated annular regions by at least one of centrifugal force and gravity.

8. A method according to claim 6 wherein the surface to be wetted comprises one side of a disk and comprising introducing the liquid metal to the activated annular regions by rotating the edge of the disk in a bath of liquid metal.

9. A method according to claim 6 wherein the surface to be wetted comprises the external surface of a cylinder and comprising introducing the liquid metal to the activated annular regions by rotating the lower part of the cylinder in a bath of liquid metal.

10. A method according to claim 6 wherein the surface to be wetted comprises the inside surface of a hollow cylinder and comprising introducing the liquid metal to the inside of the cylinder and distributing the liquid metal onto the active annular regions by rotation of the cylinder.

11. A method according to claim 7 comprising rotating the substrate surface at different rates during said activating and introducing the liquid metal.

12. A method according to claim 7 comprising maintaining the surface to be wetted in a vacuum or an inert atmosphere during said activating and introducing the liquid metal.

13. A method according to claim 1 comprising providing a metal which is liquid at room temperature.

14. A method according to claim 1 wherein said substrate is molybdenum, and the liquid metal is Galinstan.

15. Apparatus for wetting a surface of a solid substrate with a liquid metal, comprising:
a high energy beam source arranged to activate said surface; and
means for introducing the liquid metal to the surface while in the active state, the temperature of the surface being above the melting point of the liquid metal
wherein said apparatus is arranged to emit said high energy beam for progressively activating the substrate surface immediately in front of an advancing edge of the liquid metal.
